(19) United States
(12) Patent Application Publication
(10) Pub. No.: US 2009/0096107 A1
(43) Pub. Date: Apr. 16, 2009

(54) SEMICONDUCTOR INTEGRATED CIRCUIT DEVICE

(75) Inventors: Mitsuru Okazaki, Kyoto (JP); Youichi Kajiwara, Kyoto (JP); Naoki Takahashi, Kyoto (JP); Akira Shimizu, Kyoto (JP)

Correspondence Address: FISH & RICHARDSON P.C.;Citigroup Center, 153 East 53rd Street,, 52nd floor, New York, NY, 10022-4611, US

(73) Assignee: Rohm Co., Ltd, Kyoto (JP)

(21) Appl. No.: 11/917,186

(22) PCT Filed: Jun. 13, 2006
(86) PCT No.: PCT/JP2006/311805

§ 371 Date: Dec. 11, 2007

(30) Foreign Application Priority Data
Jun. 17, 2005 (JP) 2005-177140

(51) Int. Cl. H01L 23/48; H01L 23/52

(52) U.S. Cl. 257/762; 257/786; 257/E23.01; 257/E23.168

(57) ABSTRACT

In a semiconductor integrated circuit device, an element forming region and a metal wiring layer are covered with a passivation layer on a semiconductor substrate which is cut out in a rectangular shape. At four corners of the device, the passivation layer is provided with corner non-wiring regions formed directly on the semiconductor substrate. Thus, crack generation on the passivation layer due to heat stress can be suppressed.

### TECHNICAL FIELD

The present invention relates to a semiconductor integrated circuit device, and more particularly to improvement of the reliability thereof in a temperature cycle test.

### BACKGROUND ART

A temperature cycle test is conventionally imposed as one type of reliability evaluation test on semiconductor integrated circuit devices in which high reliability is required in varying use environments (e.g., a serial control LED (light emitting diode) driver for automobiles). A temperature cycle test is a test in which a semiconductor integrated circuit device is tested for reliability by being exposed alternately to a high and a low temperature (e.g., +150° C. and −65° C.) repeatedly at predetermined intervals.

When a conventional semiconductor integrated circuit device is subjected to the temperature cycle test as described above, thermal stress resulting from differences in thermal expansion coefficient among an element forming region, a metal wiring layer, and a passivation layer may produce a crack (exfoliation) in the passivation layer, in the worst case, causing even the metal wiring layer right under the passivation layer to exfoliate together. This leads to degraded reliability and reduced yields. In particular, elongate chips such as display drivers and sensors are liable to be seriously affected.

As a solution to the above described problem, a semiconductor integrated circuit device has conventionally been disclosed and proposed in which a metal wiring layer and a passivation layer have elevations and depressions (slits) formed thereon (see Patent Publication 1).

As another conventional art related to the present invention, a semiconductor chip in which a dummy pattern is formed between an identification area including an identification mark and a dicing line has been disclosed and proposed (see Patent Publication 2 filed by the applicant of the present application).

| | |
|---|---|
| Patent Publication 1 | JP-A-H05-283540 |
| Patent Publication 2 | JP-A-H05-251556 |

### DISCLOSURE OF THE INVENTION

### Problems to be Solved by the Invention

With the conventional art of Patent Publication 1, it is indeed possible to disperse thermal stress to prevent development of cracks in the passivation layer. However, the conventional art of Patent Publication 1 is disadvantageous in that it requires an extra process for forming elevations and depressions on the metal wiring layer and the passivation layer (more specifically, a process for forming elevations and depressions on an interlayer insulating film laid directly under the metal wiring layer), and this invites reduced productivity and yields.

The conventional art of Patent Publication 2 simply aims at reducing exfoliation during the dicing of a semiconductor chip and the resulting identification errors. Thus, it in no way helps prevent cracks that develop in a passivation layer during a temperature cycle test.

An object of the present invention is to provide a semiconductor integrated circuit device capable of reducing the development of cracks in a passivation layer resulting from thermal stress.

### Means for Solving the Problem

To achieve the above object, according to the present invention, a semiconductor integrated circuit device includes a passivation layer covering an element forming region and a metal wiring layer formed on a semiconductor substrate cut in a rectangular shape. Here, the semiconductor integrated circuit device has, in each of four corners thereof, a corner non-wiring region where the passivation layer is formed directly on the semiconductor substrate (first configuration).

According to the present invention, in the semiconductor integrated circuit device having the first configuration described above, the corner non-wiring region may be a triangular region enclosed by a first line connecting a corner of the semiconductor integrated circuit device and a first point located on an edge extending from the corner, a second line connecting the corner and a second point located on another edge extending from the corner, and a third line connecting the first and second points, with no part of metal wiring layer formed in the triangular region (second configuration).

According to the present invention, in the semiconductor integrated circuit device having the second configuration described above, the first and second lines each may have a length of 250 μm (third configuration).

According to the present invention, in the semiconductor integrated circuit device having one of the first to third configurations described above, one side of the semiconductor substrate may be two times or more (more specifically, five times or more) as long as another side that is perpendicular to the one side (fourth configuration).

According to the present invention, in the semiconductor integrated circuit device having one of the first to fourth configurations described above, a plurality of driver circuits or sensor circuits may be formed in the element forming region (fifth configuration).

According to the present invention, in the semiconductor integrated circuit device having one of the first to fifth configurations described above, the metal wiring layer may be an aluminum wiring layer or a copper wiring layer, or a rewiring layer thereof, and the passivation layer may be a polyimide resin layer, a silicon oxide layer, or a silicon nitride layer (sixth configuration).

### ADVANTAGES OF THE INVENTION

With a semiconductor integrated circuit device of the present invention, it is possible to reduce the development of cracks in the passivation layer resulting from thermal stress, and thus to improve the reliability of the semiconductor integrated circuit device in the temperature cycle test.

### BRIEF DESCRIPTION OF DRAWINGS

FIG. 1A is a top view showing a semiconductor integrated circuit device according to a first embodiment of the present invention.

FIG. 1B is a sectional view showing the semiconductor integrated circuit device according to the first embodiment of the present invention.

FIG. 2A is a top view showing a semiconductor integrated circuit device according to a second embodiment of the present invention.

FIG. 2B is a sectional view showing the semiconductor integrated circuit device according to the second embodiment of the present invention.

FIG. 3A,

FIG. 3B, and

FIG. 3C are top views showing a semiconductor integrated circuit device according to a third embodiment of the present invention.

### LIST OF REFERENCE SYMBOLS

10 semiconductor integrated circuit device
11 semiconductor substrate
12 element forming region (impurity diffusion region)
13 metal wiring layer
13′ rewiring layer
14 passivation layer
14′ insulating layer
CC1-CC4 corner non-wiring regions
a corner
X, Y edges
x, y points on edges X and Y

### BEST MODE FOR CARRYING OUT THE INVENTION

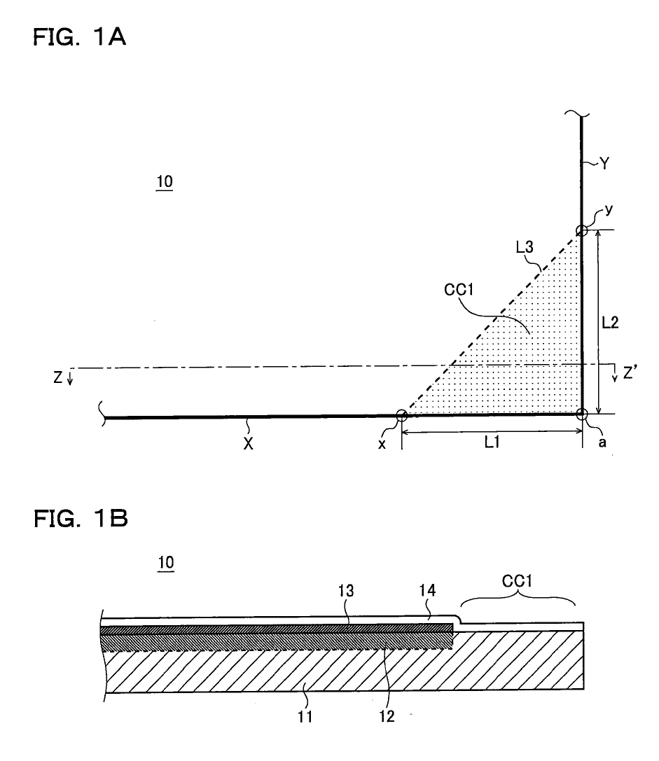

FIG. 1A is a top view and FIG. 1B is a sectional view along line Z-Z′ in FIG. 1A, both showing a semiconductor integrated circuit device according to a first embodiment of the present invention.

As shown in FIG. 1A, the semiconductor integrated circuit device 10 of this embodiment is a semiconductor chip cut apart along a prescribed dicing lines, and dividing it apart gives it four corners and four edges each connecting two adjoining corners. FIG. 1A shows, of all these corners and edges, only one corner “a” and two edges X and Y extending from it in mutually perpendicular directions.

As shown in FIG. 1B, in the semiconductor integrated circuit device 10 of this embodiment, an element forming region (impurity diffusion region) 12 is formed on a semiconductor substrate 11 cut out in a rectangular shape, and further on top a metal wiring layer 13 and then a passivation layer 14 are formed. The semiconductor substrate 11 is cut out so that one side thereof is two times or more (more specifically, five times or more) as long as another side that is perpendicular to that one side. The semiconductor integrated circuit device 10 is a display driver or a sensor device, and thus, in the element forming region 12 thereof, a plurality of display driver circuits or sensor circuits are formed. Though not shown in the figure, in the semiconductor integrated circuit device 10 of this embodiment, an interlayer insulating film, an element separating region, etc. are also formed.

The semiconductor substrate 11 may be a silicon substrate. A metal having high electric conductivity such as aluminum, copper, or gold is preferable as the material of the metal wiring layer 13. As the material of the passivation layer 14 that covers and protects the element forming region 12 and the metal wiring layer 13, polyimide resin, which is an electrically insulating material, may be used.

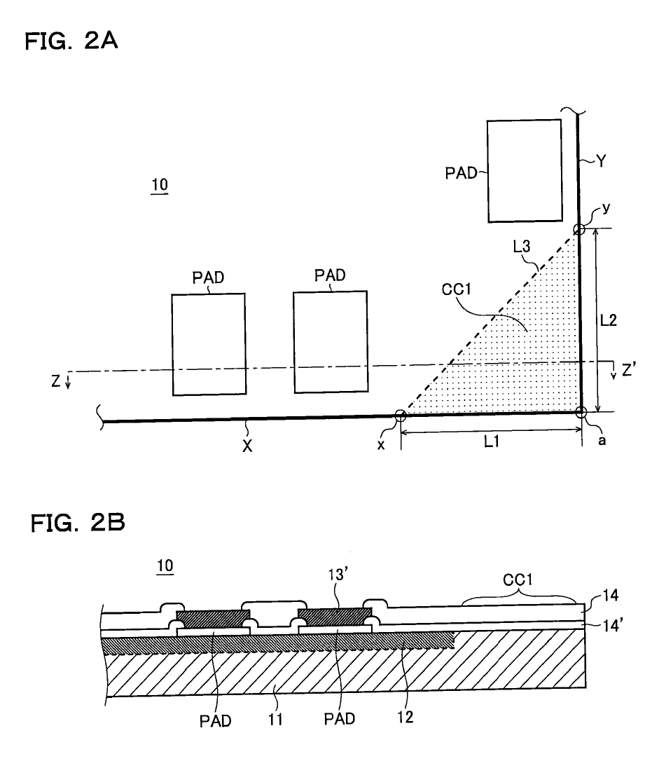

In the present specification, the metal wiring layer 13 is assumed to include in its concept a rewiring layer 13′ as shown in FIG. 2B. The passivation layer 14 is assumed to include in its concept an insulating layer 14′ made of a silicon oxide (e.g., SiO₂) or a silicon nitride (e.g., SiN) in addition to the already mentioned passivation layer 14 made of polyimide resin or the like.

Here, as shown in FIGS. 1A and 1B, in order to improve its reliability in a temperature cycle test, the semiconductor integrated circuit device 10 has, in each of the four corners thereof (regions in which thermal stress is liable to concentrate), a corner non-wiring region CC1 where the passivation layer 14 is formed directly on the semiconductor substrate 11.

More specifically, each corner non-wiring region CC1 in this embodiment is a triangular region enclosed by a first line L1 connecting a corner “a” and a point x located on an edge X, a second line L2 connecting the corner “a” and a point y located on another edge Y, and a third line L3 connecting the points x and y (the dotted area in FIG. 1A). Inside this region, no part of the metal wiring layer 13, which is greatly different in thermal expansion coefficient from the passivation layer 14, is formed.

Although only the corner “a” is shown in FIG. 1A, a corner non-wiring region as described above is formed in each of the other three corners.

By forming a corner non-wiring region CC1 in each of the four corners of the semiconductor integrated circuit device 10 as described above, the difference in thermal expansion coefficient between the passivation layer 14 and a layer directly thereunder can be minimized. Thus, it is possible to reduce the thermal stress itself applied to the passivation layer 14, and thereby to reduce the development of cracks therein.

However, quite naturally, an excessively large corner non-wiring region CC1, even though effective in reducing cracks, leads to an unduly low element density. To prevent this, it is preferable that the corner non-wiring region CC1 be given a minimum size necessary to appropriately prevent cracks in the passivation layer 14. For example, the first and second lines L1 and L2 may be designed to be about 250 μm long. It should be noted that the size mentioned above is only an example and the size of the corner non-wiring region CC1 may be appropriately adjusted according to factors such as the material and thickness of the passivation layer 14.

The present invention may be carried out in any manner other than specifically described above as embodiments, and permits any variations and modifications within the spirit thereof.

For example, although it is assumed in the embodiments described above that the first and second lines L1 and L2 that determine the corner non-wiring region CC1 have the same length, the configuration of the present invention is not meant to be limited to this, but the two lines may have different lengths.

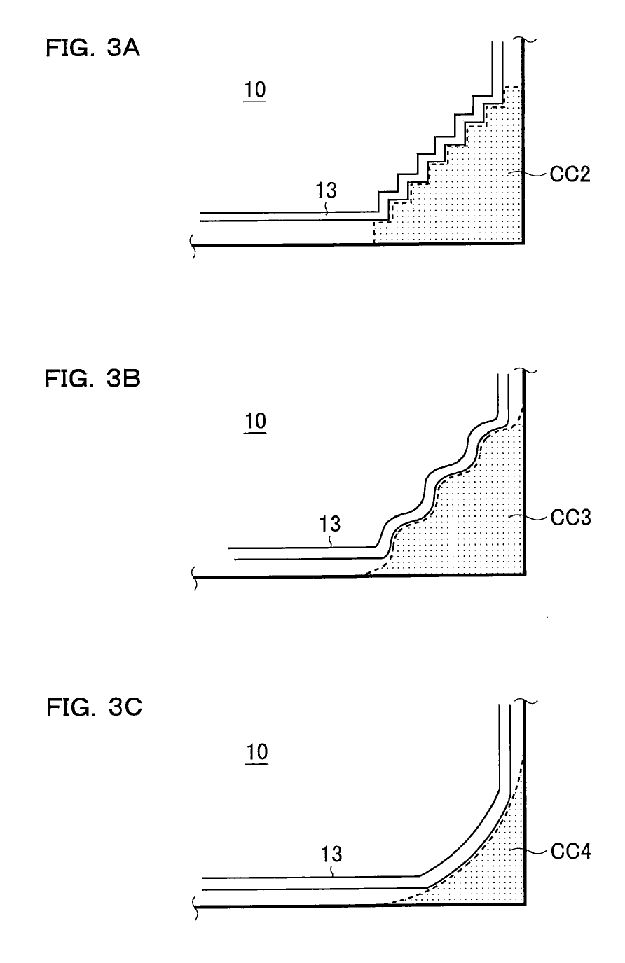

Also, though it is assumed in the embodiments described above that the corner non-wiring region CC1 has a triangular shape, this is not meant to limit the shape of the corner non-wiring region CC1, but any shape is permissible as long as concentration of thermal stress can be alleviated. For example, the corner non-wiring region CC1 may be enclosed by the first and second lines L1 and L2, and instead of the third line L3, a series of straight lines, a free curve, or a circular arc as shown in FIGS. 3A, 3B, and 3C, respectively (the dotted regions in the figures).

### INDUSTRIAL APPLICABILITY

The present invention offers technology that is useful for improvement of the reliability and yields of a semiconductor integrated circuit device, and can be suitably used, for example, in semiconductor integrated circuit devices incorporated in electronic devices for automobiles.

1. A semiconductor integrated circuit device comprising a passivation layer covering an element forming region and a metal wiring layer on a rectangular shaped semiconductor substrate, wherein the semiconductor integrated circuit device has, in each of four corners thereof, a corner non-wiring region where the passivation layer is directly on the semiconductor substrate.

2. The semiconductor integrated circuit device of claim 1, wherein the corner non-wiring region is a triangular region enclosed by a first line connecting a corner of the semiconductor integrated circuit device and a first point located on an edge extending from the corner, a second line connecting the corner and a second point located on another edge extending from the corner, and a third line connecting the first and second points, with no part of the metal wiring layer formed inside the triangular region.

3. The semiconductor integrated circuit device of claim 2, wherein the first and second lines each have a length of 250 μm.

4. The semiconductor integrated circuit device of claim 1, wherein one side of the semiconductor substrate is at least two times as long as another side that is perpendicular to the one side.

5. The semiconductor integrated circuit device of claim 1, wherein a plurality of driver circuits or sensor circuits are in the element forming region.

6. The semiconductor integrated circuit device of claim 1, wherein the metal wiring layer is an aluminum wiring layer or a copper wiring layer, or a rewiring layer thereof, and the passivation layer is a polyimide resin layer, a silicon oxide layer, or a silicon nitride layer.
